(19) United States
(12) Patent Application Publication
(10) Pub. No.: US 2020/0194260 A1
(43) Pub. Date: Jun. 18, 2020

(54) LASER IRRADIATION DEVICE, LASER IRRADIATION METHOD AND PROJECTION MASK

(71) Applicant: V Technology Co., Ltd., Yokohama-shi (JP)

(72) Inventor: Michinobu Mizumura, Yokohama-shi (JP)

(21) Appl. No.: 16/800,066

(22) Filed: Feb. 25, 2020

Related U.S. Application Data
(63) Continuation of application No. PCT/JP2018/030866, filed on Aug. 21, 2018.

(30) Foreign Application Priority Data
Sep. 26, 2017 (JP) 2017-185497

(51) Int. Cl. H01L 21/02; G02B 3/00; H01L 21/67; H01L 21/268

(52) U.S. Cl. CPC H01L 21/02678; H01L 21/268; H01L 21/67115; G02B 3/0037

(57) ABSTRACT

A laser irradiation device includes a light source that generates laser light, a projection lens that radiates the laser light to a predetermined region of an amorphous silicon thin film deposited on a substrate, and a projection mask pattern provided on the projection lens and having a plurality of opening portions so that a predetermined region of the amorphous silicon thin film is irradiated with the laser light, wherein each of the plurality of opening portions has a transmittance based on a projection magnification of the projection lens.

### TECHNICAL FIELD

This disclosure relates to formation of a thin film transistor and, more particularly, to a laser irradiation device, a laser irradiation method, and a projection mask that irradiate an amorphous silicon thin film with laser light and form a polysilicon thin film.

### BACKGROUND

As a thin film transistor having an inverted staggered structure, there is a thin film transistor that uses an amorphous silicon thin film for a channel region. However, since the amorphous silicon thin film has low electron mobility, when the amorphous silicon thin film is used for a channel region, there is a problem that the mobility of charges in the thin film transistor is reduced.

Therefore, there is a technique in which a predetermined region of an amorphous silicon thin film is instantaneously heated by laser light to be re-crystallized, a polysilicon thin film having high electron mobility is formed, and the polysilicon thin film is used for a channel region.

For example, Japanese Unexamined Patent Application, First Publication No. 2016-100537 discloses an amorphous silicon thin film formed on a substrate, and then the amorphous silicon thin film is irradiated with laser light such as an excimer laser and laser-annealed to perform a process of melting and solidifying in a short time and to crystallize the polysilicon thin film. JP '537 discloses that a channel region between a source and a drain of a thin film transistor can be formed as a polysilicon thin film having high electron mobility by performing that process, and an operation speed of a transistor can be increased.

JP '537 describes that the laser light is transmitted through a plurality of microlenses included in a microlens array, and a plurality of locations on the substrate are laser-annealed by one irradiation with the laser light. However, each of the plurality of microlenses included in the microlens array may have a different shape. Therefore, energy densities of the laser light transmitted through the plurality of microlenses may vary from each other, and the electron mobility of the polysilicon thin film formed using the laser light may also vary. Since characteristics of a thin film transistor depend on an electron transfer density, a variation in an energy density of the laser light transmitted through each of the plurality of microlenses causes a problem in that a variation in characteristics of a plurality of thin film transistors on the substrate occurs.

It could therefore be helpful to provide a laser irradiation device, a laser irradiation method, and a projection mask that are able to suppress variation in characteristics of a plurality of thin film transistors included in a substrate.

### SUMMARY

We thus provide:
A laser irradiation device includes a light source that generates laser light, a projection lens that radiates the laser light to a predetermined region of an amorphous silicon thin film deposited on a substrate, and a projection mask pattern provided on the projection lens and has a plurality of opening portions so that a predetermined region of the amorphous silicon thin film is irradiated with the laser light, wherein each of the plurality of opening portions has a transmittance based on a projection magnification of the projection lens.

The projection lens may be a plurality of microlenses included in a microlens array capable of separating the laser light, and each of the plurality of opening portions may have a transmittance based on a projection magnification of the microlenses.

Each of the plurality of opening portions may have a transmittance determined on the basis of a difference between a maximum value of the projection magnification of each of the plurality of microlenses and the projection magnification of the microlenses.

The transmittance of one microlens, at which the projection magnification is a maximum value, among the plurality of microlenses may be a predetermined transmittance, and each of the other microlenses among the plurality of microlenses may have a transmittance determined on the basis of the predetermined transmittance and the difference between the maximum value and the projection magnification of each of the other microlenses.

Each of the plurality of opening portions may have a size determined on the basis of the projection magnification of each of the plurality of microlenses.

Each of the plurality of opening portions may have a rectangular shape, and a length and a width of the rectangular shape may be determined on the basis of the projection magnification of each of the plurality of microlenses.

The projection lens may radiate the laser light to an amorphous silicon thin film deposited to a region corresponding to a region between a source electrode and a drain electrode included in a thin film transistor and may form a polysilicon thin film.

A laser irradiation method includes a step of generating laser light, a step of irradiating a predetermined region of an amorphous silicon thin film deposited on a substrate with the laser light using a projection lens having a projection mask pattern including a plurality of opening portions, and a step of moving the substrate in a predetermined direction whenever the laser light is radiated, wherein each of the plurality of opening portions has a transmittance based on a projection magnification of the projection lens.

The projection lens may be a plurality of microlenses included in a microlens array capable of separating the laser light, and each of the plurality of opening portions may have a transmittance based on a projection magnification of the microlenses.

Each of the plurality of opening portions may have a transmittance determined on the basis of a difference between a maximum value in the projection magnification of each of the plurality of microlenses and the projection magnification of the microlens.

Each of the plurality of opening portions may have a size determined on the basis of the projection magnification of each of the plurality of microlenses.

A projection mask is disposed on a projection lens that radiates laser light generated from a light source, wherein a plurality of opening portions are provided in the projection mask so that a predetermined region of an amorphous silicon thin film deposited on a substrate that moves in a predetermined direction is irradiated with the laser light, and each of the plurality of opening portions has a transmittance based on a projection magnification of the projection lens.

The projection lens may be a plurality of microlenses included in a microlens array capable of separating the laser light, and each of the plurality of opening portions may have a transmittance based on a projection magnification of the microlenses.

Each of the plurality of opening portions may have a transmittance determined on the basis of a difference between a maximum value of the projection magnification of each of the plurality of microlenses and the projection magnification of the microlenses.

Each of the plurality of opening portions may have a size determined on the basis of the projection magnification of each of the plurality of microlenses.

It is possible to provide a laser irradiation device, a laser irradiation method, and a projection mask that can suppress variation in characteristics of a plurality of thin film transistors included in a substrate.

### BRIEF DESCRIPTION OF THE DRAWINGS

FIG. 1 is a view showing a configuration of a laser irradiation device 10.

FIG. 2 is a view showing a configuration of a microlens array 13.

FIG. 3 is a schematic view showing an example of a thin film transistor 20 in which a predetermined region has been annealed.

FIG. 4 is a schematic view showing an example of a substrate 30 on which a laser irradiation device 10 radiates laser light 14.

FIG. 5 is a view showing another configuration of the microlens array 13.

FIG. 6 is a table showing an example of a correspondence relationship regarding a plurality of microlenses 17 included in the microlens array 13.

FIG. 7 is a view showing yet another configuration of the microlens array 13.

FIGS. 8A and 8B are views showing configurations of the microlens array 13 and a projection mask pattern 15, respectively.

FIG. 9 is a table showing another example of the correspondence relationship regarding the plurality of microlenses 17 included in the microlens array 13.

FIG. 10 is a table showing yet another example of the correspondence relationship regarding the plurality of microlenses 17 included in the microlens array 13.

FIG. 11 is a view showing another configuration of the laser irradiation device 10.

### DESCRIPTION OF REFERENCES

10 Laser irradiation device
11 Laser light source
12 Coupling optical system
13 Microlens array
14 Laser light
15 Projection mask pattern
16 Opening portion (transmission region)
17 Microlens
18 Projection lens
20 Thin film transistor
21 Amorphous silicon thin film
22 Polysilicon thin film
23 Source
24 Drain
30 Substrate

### DETAILED DESCRIPTION

Hereinafter, examples will be described in detail with reference to the accompanying drawings.

### FIRST EXAMPLE

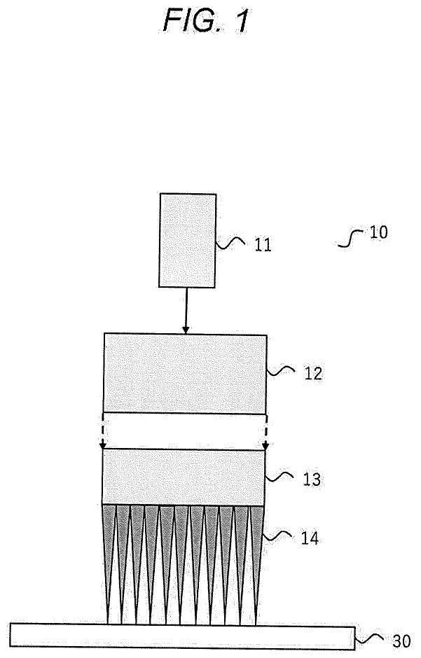

FIG. 1 is a view showing a configuration of a laser irradiation device 10 according to a first example.

In a manufacturing process of a semiconductor device such as a thin film transistor (TFT) 20, a laser irradiation device 10 is, for example, a device that radiates laser light to a channel-region formation scheduled region and performs an annealing process to re-crystallize the channel-region formation scheduled region.

The laser irradiation device 10 is used, for example, when a thin film transistor of a pixel such as a peripheral circuit of a liquid crystal display device is formed. When such a thin film transistor is formed, first, a gate electrode made of a metal film such as Al is patterned and formed on a substrate 30 by sputtering. Then, a gate insulating film made of a SiN film is formed on an entire surface of the substrate 30 by a low-temperature plasma CVD method. Thereafter, an amorphous silicon thin film 21 is formed on the gate insulating film by, for example, a plasma CVD method. That is, the amorphous silicon thin film 21 is formed (deposited) on the entire surface of the substrate 30. Finally, a silicon dioxide (SiO₂) film is formed on the amorphous silicon thin film 21. Then, a predetermined region on the gate electrode of the amorphous silicon thin film 21 (a region of the thin film transistor 20 that will be a channel region) is irradiated with laser light 14 by the laser irradiation device 10 exemplified in FIG. 1, an annealing process is performed, and thus the predetermined region is re-crystallized and converted into polysilicon. The substrate 30 is, for example, a glass substrate, but the substrate 30 is not necessarily made of a glass material and may be a substrate made of any material such as a resin substrate made of a material such as a resin.

As shown in FIG. 1, in the laser irradiation device 10, a beam system of the laser light 14 emitted from a laser light source 11 is expanded by a coupling optical system 12, and an illuminance distribution is made uniform. The laser light source 11 is, for example, an excimer laser that emits the laser light 14 having a wavelength of 308 nm or 248 nm with a predetermined repetition cycle.

Thereafter, the laser light 14 is separated into a plurality of laser lights 14 by a plurality of opening portions (transmission regions) of a projection mask pattern 15 (not shown) provided on the microlens array 13 and is then radiated on a predetermined region of the amorphous silicon thin film 21. The projection mask pattern 15 is provided on the microlens array 13, and the predetermined region is irradiated with the laser light 14 by the projection mask pattern 15. Then, a predetermined region of the amorphous silicon thin film 21 is instantaneously heated and melted, and a part of the amorphous silicon thin film 21 becomes a polysilicon thin film 22. The projection mask pattern 15 may be referred to as a projection mask.

The polysilicon thin film 22 has higher electron mobility than that of the amorphous silicon thin film 21 and is used as a channel region to electrically connect a source 23 to a drain 24 in the thin film transistor 20. Although the example of FIG. 1 shows an example in which the microlens array 13 is used, the microlens array 13 does not necessarily need to be used, and the laser light 14 may be radiated using one projection lens. In the example, the polysilicon thin film 22 is formed using the microlens array 13 will be described as an example.

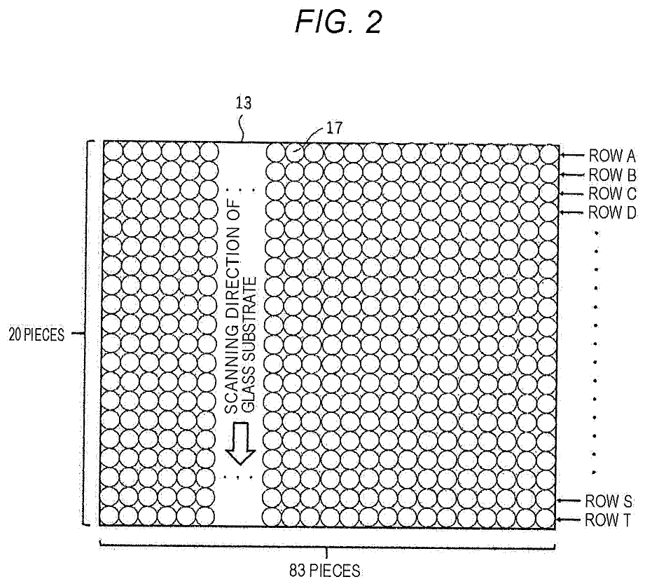

FIG. 2 is a view showing a configuration of the microlens array 13 used for the annealing process. In the microlens array 13, 20 microlenses 17 are disposed in one column (or one row) in a scanning direction. The laser irradiation device 10 radiates the laser light 14 to a predetermined region of the amorphous silicon thin film 21 using at least a part of the 20 microlenses 17 included in one column (or one row) of the microlens array 13. The number of microlenses 17 in one column (or one row) included in the microlens array 13 is not limited to 20 and may be any number.

The microlens array 13 includes the 20 microlenses 17 in one column (or one row) and includes, for example, 165 microlenses 17 in one row (or one column). In addition, it is needless to say that 165 is an example, and any number may be used.

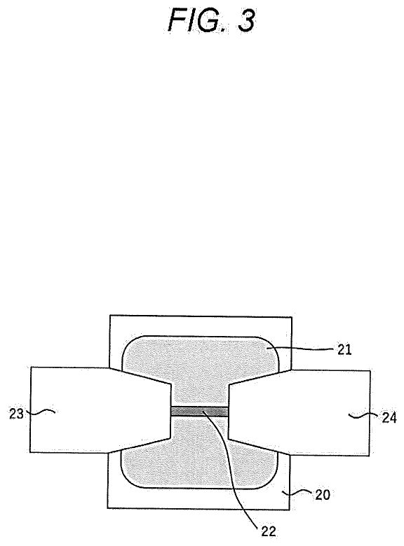

FIG. 3 is a schematic view showing an example of the thin film transistor 20 in which a predetermined region has been annealed. The thin film transistor 20 is formed by first forming the polysilicon thin film 22 and then forming the source 23 and the drain 24 at both ends of the formed polysilicon thin film 22.

In the thin film transistor 20, the polysilicon thin film 22 is formed between the source 23 and the drain 24. The laser irradiation device 10 radiates the laser light 14 on a predetermined region of the amorphous silicon thin film 21 using, for example, the 20 microlenses 17 included in one column (or one row) of the microlens array 13 shown in FIG. 3. That is, the laser irradiation device 10 irradiates the predetermined region of the amorphous silicon thin film 21 with 20 shots of the laser light 14. As a result, a predetermined region of the amorphous silicon thin film 21 is instantaneously heated and melted in a region in which the thin film transistor 20 is to be formed and becomes the polysilicon thin film 22.

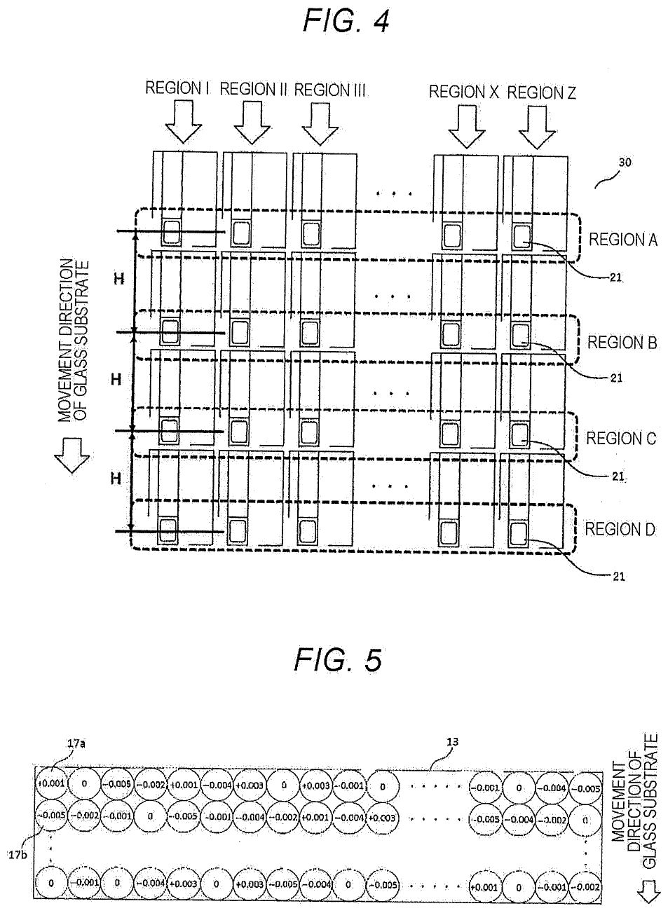

FIG. 4 is a schematic view showing an example of the substrate 30 on which the laser irradiation device 10 radiates the laser light 14. The substrate 30 does not necessarily need to be made of a glass material and may be a substrate made of any material such as a resin substrate made of a material such as a resin. As shown in FIG. 4, the substrate 30 includes a plurality of pixels 31, and each of the pixels 31 includes the thin film transistor 20. The thin film transistor 20 performs light transmission control in each of the plurality of pixels 31 by electrically turning them on/off. The amorphous silicon thin film 21 is provided on the entire surface of the substrate 30. The predetermined region of the amorphous silicon thin film 21 is a portion that will be a channel region of the thin film transistor 20.

The laser irradiation device 10 irradiates the predetermined region (the region of the thin film transistor 20 which will be the channel region) of the amorphous silicon thin film 21 with the laser light 14. The laser irradiation device 10 radiates the laser light 14 with a predetermined cycle and moves the substrate 30 at a time when the laser light 14 is not radiated so that the next predetermined region of the amorphous silicon thin film 21 is irradiated with the laser light 14. As shown in FIG. 4, the amorphous silicon thin film 21 is disposed on the entire surface of the substrate 30. Then, the laser irradiation device 10 irradiates the predetermined region of the amorphous silicon thin film 21 disposed on the substrate 30 with the laser light 14 with a predetermined cycle.

Then, the laser irradiation device 10 irradiates a predetermined region of the amorphous silicon thin film 21 on the substrate with the laser light 14 using the microlens array 13. The laser irradiation device 10 irradiates, for example, a region A shown in FIG. 4 in the amorphous silicon thin film 21 provided (deposited) on the entire surface of the substrate 30 with the laser light 14. Further, the laser irradiation device 10 also irradiates a region B shown in FIG. 4 in the amorphous silicon thin film 21 provided (deposited) on the entire surface of the substrate 30 with the laser light 14.

The laser irradiation device 10 can radiate the laser light 14 using each of the 20 microlenses 17 included in one column (or one row) of the microlens array 13 shown in FIG. 2 to perform an annealing process.

In this example, the region A shown in FIG. 4 in the amorphous silicon thin film 21 provided (deposited) on the entire surface of the substrate 30 is first irradiated with the laser light 14 using first microlenses 17 in a column A of the microlens array 13 shown in FIG. 2. Thereafter, the substrate 30 is moved by a predetermined interval “H.” While the substrate 30 is moving, the laser irradiation device 10 may stop irradiation with the laser light 14. Then, after the substrate 30 has moved by “H,” the region A shown in FIG. 4 in the amorphous silicon thin film 21 is irradiated with the laser light 14 using second microlenses 17 in a column B of the microlens array 13 shown in FIG. 2. The laser irradiation device 10 may stop the irradiation with the laser light 14 while the substrate 30 is moving or may irradiate the substrate 30 which is continuously moving with the laser light 14.

In addition, an irradiation head (that is, the laser light source 11, the coupling optical system 12, the microlens array 13, and the projection mask pattern 15) of the laser irradiation device 10 may move with respect to the substrate 30.

The laser irradiation device 10 repeatedly performs this process and finally irradiates a region A shown in FIG. 4 in the amorphous silicon thin film 21 with the laser light 14 using the microlenses 17 in a column T (that is, the last microlenses 17) of the microlens array 13 shown in FIG. 2. As a result, the region A of the amorphous silicon thin film 21 is irradiated with the laser light 14 using each of the 20 microlenses 17 included in one column (or one row) of the microlens array 13 shown in FIG. 2.

Similarly, the laser irradiation device 10 also irradiates the region B shown in FIG. 4 in the amorphous silicon thin film 21 with the laser light 14 using each of the 20 microlenses 17 included in one column (or one row) of the microlens array 13 shown in FIG. 2. However, since a position of the region B is different from the region A by “H” in a movement direction of the substrate 30, a timing at which the laser light 14 is irradiated is delayed by one irradiation. That is, when the region A is irradiated with the laser light 14 using the second microlenses 17 in the column B shown in FIG. 2, the region B is irradiated with the laser light 14 using the first microlenses 17 in the column A shown in FIG. 2. Then, when the region A is irradiated with the laser light 14 using the twentieth microlenses 17 (that is, the last microlenses 17) in a column T shown in FIG. 2, the region B is irradiated with the laser light using the microlenses 17 in a previous column S. Then, the region B is irradiated with the laser light using the microlenses 17 in the column T (that is, the last microlens 17).

Since each of the plurality of microlenses 17 included in the microlens array 13 has a certain variation, and a variation in a lens curvature is caused by the variation, a projection magnification (a projection magnification of the laser light 14 on the substrate 30) may be different for each of the plurality of microlenses 17. When the projection magnification is different, a variation in energy densities of the laser light irradiated on the substrate 30 occurs, and thus a variation in a result of the annealing process occurs. Accordingly, a variation in the electron mobility of the polysilicon thin film formed on the substrate 30 also occurs and, as a result, there is a problem that a variation in characteristics of the thin film transistor 20 occurs.

Therefore, in the first example, the projection magnification of each of the plurality of microlenses 17 included in the microlens array 13 is measured, and a transmittance of the laser light 14 in each of the plurality of microlenses 17 is adjusted on the basis of the lowest projection magnification among the measured projection magnifications. The laser light 14 irradiated by each of the plurality of microlenses 17 is made to have substantially the same energy density on the substrate by adjusting the transmittance of the laser light 14. As a result, the electron mobility of the polysilicon thin film formed by the laser light 14 irradiated by each of the plurality of microlenses 17 is also substantially the same, and thus the variation in the characteristics of the thin film transistor 20 can be reduced.

As described above, in the first example, a transmittance of the opening portions (the transmission region) of the projection mask pattern 15 provided in the microlens array 13 is adjusted to adjust the transmittance of the laser light 14 in each of the plurality of microlenses 17. Specifically, the projection magnification of each of the plurality of microlenses 17 included in the microlens array 13 is measured, and the transmittance of the opening portion (the transmission region) of the projection mask pattern 15 corresponding to each of the plurality of microlenses 17 is set on the basis of the lowest projection magnification among the measured projection magnifications.

When the projection magnification of the microlens 17 is high, the transmittance is low, and the transmittance cannot be increased. Therefore, the transmittance of each of the other microlenses 17 is adjusted according to the microlens 17 having the largest projection magnification (that is, the lowest transmittance). For example, assuming that the transmittance of the microlens 17 having the largest projection magnification is 100%, the transmittance of each of the other microlenses 17 is set accordingly. Also, the transmittance of the microlens 17 having the largest projection magnification does not necessarily need to be 100% and may be less than 100%.

FIG. 5 is a schematic view showing the projection magnification of the plurality of microlenses 17 included in the microlens array 13. The projection magnification is indicated by an increase or decrease from a predetermined value on the basis of the predetermined value. The microlenses 17 have different projection magnifications. For example, the projection magnification of a microlens 17a is “+0.001%,” while the projection magnification of a microlens 17b is “−0.005%.” In addition, as described above, when the projection magnification becomes “+,” the energy density of the laser light 14 on the substrate 30 decreases, and when the projection magnification becomes “−,” the energy density of the laser light 14 on the substrate 30 increases.

Each of the microlenses 17 included in the microlens array 13 has a different projection magnification. Also, the projection magnification is a projection magnification when the laser light 14 transmitted through each of the plurality of microlenses 17 is projected on the substrate 30.

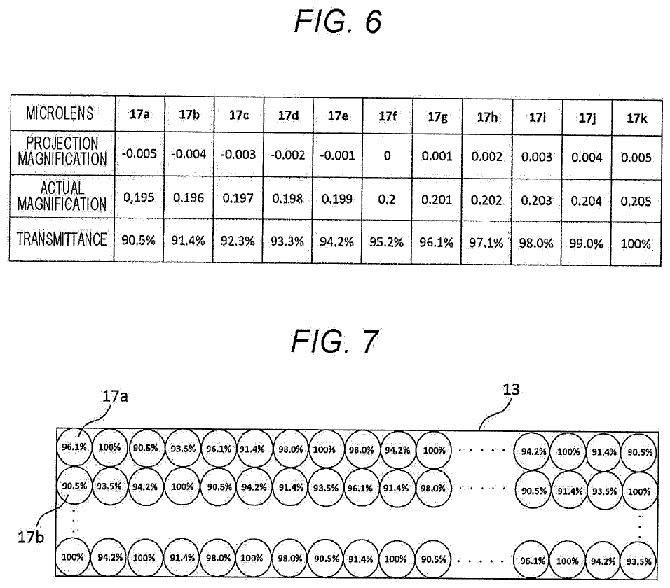

FIG. 6 is a table showing a correspondence relationship between the projection magnification of the microlens 17, an actual projection magnification, and the transmittance set in the opening portion of the projection mask pattern 15. Among the microlens 17 included in the microlens array 13, a microlens 17k having the lowest projection magnification is set to have a transmittance of 100%. In an example of FIG. 6, since the projection magnification of the microlens 17k is “0.005” (the actual projection magnification is “0.205”) which is the lowest, the transmittance of the laser light 14 from the microlens 17k is set to “100%.”

Then, the transmittance of the laser light through each of the other microlenses 17 is set on the basis of the projection magnification of the microlens 17k having a transmittance of 100%. For example, the microlens 17a of which the projection magnification is “−0.005” (the actual projection magnification is “0.195”) is set to have a transmittance of “90.5%” on the basis of a difference from the projection magnification of “0.005” of the microlens 17k (the actual projection magnification is “0.205”). Further, since the projection magnification of the microlens 17b is “−0.004” (the actual projection magnification is “0.196”), the transmittance is set to “91.4%” on the basis of the difference from the projection magnification of “0.005” of the microlens 17k (the actual projection magnification is “0.205”). The transmittance of each of the other microlenses c to j is similarly set.

For each of the microlenses 17 included in the microlens array 13 of FIG. 2, the transmittance (the transmittance of the opening portion (the transmission region) of the projection mask pattern 15) is set on the basis of the correspondence relationship between the “projection magnification of each of the microlenses 17,” the “actual projection magnification,” and the “transmittance which is set to the opening portion of the projection mask pattern 15” exemplified in FIG. 6.

FIG. 7 is a view showing a state of the transmittance set for each of the microlenses 17 included in the microlens array 13 on the basis of the correspondence relationship exemplified in FIG. 6. The microlens array 13 shown in FIG. 7 is the same as the microlens array 13 shown in FIG. 5. As exemplified in FIG. 5, each of the plurality of microlenses 17 included in the microlens array 13 has a different projection magnification. Therefore, the transmittance of each of the plurality of microlenses 17 (the transmittance of the opening portion (the transmission region) of the projection mask pattern 15) is set as shown in FIG. 7 on the basis of the correspondence relationship exemplified in FIG. 6.

As shown in FIG. 5, since the projection magnification of the microlens 17a is “+0.001” and, as shown in FIG. 7, the transmittance is set to “96.1%.” Further, since the projection magnification of the microlens 17b is “−0.005,” the transmittance is set to “90.5%.” Similarly, the transmittance of each of the other microlenses 17 is set on the basis of the projection magnification.

As a result, the transmittance of each of the plurality of microlenses 17 (that is, the transmittance of the opening portion (the transmission region) of the projection mask pattern 15) is set so that the energy density of the laser light 14 on the substrate is substantially uniform. Specifically, transmittance of each of the microlenses 17 is set so that all the microlenses 17 included in the microlens array 13 have substantially the same energy density on the substrate as that of the microlens 17 having the lowest projection magnification.

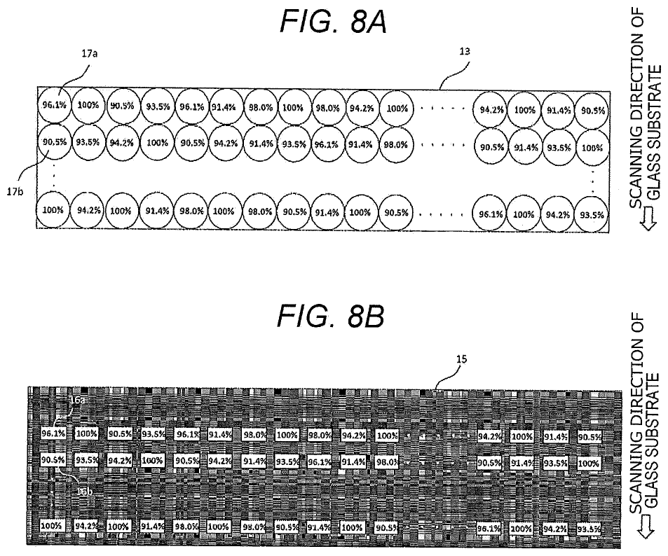

FIGS. 8A and 8B are views explaining transmittance of the opening portion 16 of the projection mask pattern 15 according to the first example. The transmittance of each of a plurality of opening portions 16 included in the projection mask pattern 15 is set so that the laser light 14 is transmitted at the transmittance set for the corresponding microlens 17. Since an opening portion 16a corresponds to the microlens 17a of which the transmittance is set to “96.1%,” the transmittance of the laser light 14 through the opening portion 16a is set to “96.1%.” Also, since an opening portion 16b corresponds to the microlens 17b of which the transmittance is set to “90.5%,” the transmittance of the laser light 14 through the opening portion 16b is set to “90.5%.” Similarly, the transmittance of each of the plurality of opening portions 16 included in the projection mask pattern 15 is the transmittance set for each of the corresponding microlenses 17. As a result, the laser light 14 transmitted through the projection mask pattern 15 has substantially a uniform energy density on the substrate 30.

In one row of the projection mask pattern 15, a total transmittance (a total value of the transmittances) of 20 opening portions 16 is preferably set to a predetermined value (a predetermined area). That is, the total transmittance of the opening portions 16 in each of the columns of the projection mask pattern 15 exemplified in FIG. 8B is set to a predetermined value (a predetermined transmittance). As a result, regardless of which “row” of the projection mask pattern 15 is used, a sum of the energy densities of the laser light 14 irradiated on the predetermined region of the amorphous silicon thin film 21 becomes constant. In one row of the projection mask pattern 15, the total transmittance of the 20 opening portions 16 does not necessarily need to be set to a predetermined value (a predetermined transmittance), and the total transmittance of the laser light 14 may be different for each of the “rows.”

Further, in the example of FIGS. 8A and 8B, the opening portion (the transmission region) 16 of the projection mask pattern 15 is provided to be orthogonal to the movement direction (the scanning direction) of the substrate 30. Also, the opening portion (the transmission region) 16 of the projection mask pattern 15 does not necessarily need to be orthogonal to the movement direction (the scanning direction) of the substrate 30 and may be provided parallel (substantially parallel) to the movement direction (the scanning direction).

Operation of the laser irradiation device 10 according to the first example will be described. First, the substrate 30 moves by a predetermined distance whenever the microlens array 13 is irradiated with the laser light 14. The predetermined distance is a distance “H” between the plurality of thin film transistors 20 on the substrate 30. The laser irradiation device 10 stops the irradiation with the laser light 14 while the substrate 30 is moved by the predetermined distance.

After the substrate 30 has been moved by the predetermined distance “H,” the laser irradiation device 10 radiates the laser light 14 again using the microlenses 17 included in the microlens array 13. In the first example, since the microlens array 13 shown in FIG. 2 is used, one amorphous silicon thin film 21 is irradiated with the laser light 14 by the 20 microlenses 17.

Then, after the polysilicon thin film 22 is formed in a predetermined region of the amorphous silicon thin film 21 of the substrate 30 using laser annealing, the source 23 and the drain 24 are formed in the thin film transistor 20 in another process.

As described above, since the transmittance of each of the plurality of microlenses 17 is set so that the energy density of the laser light 14 on the substrate is set to be substantially uniform, the variation in the energy density applied to the substrate 30 due to the variation in the projection magnification of each of the plurality of microlenses 17 can be reduced. Since the energy densities of the laser light 14 are substantially the same, the variation in the electron mobility of the polysilicon thin film formed using the laser light 14 is reduced. As a result, it is possible to reduce the variation in the characteristics of the plurality of thin film transistors on the substrate.

### SECOND EXAMPLE

A second example includes a size of the opening portion 16 of the projection mask pattern 15 being set on the basis of the projection magnification of the microlens 17.

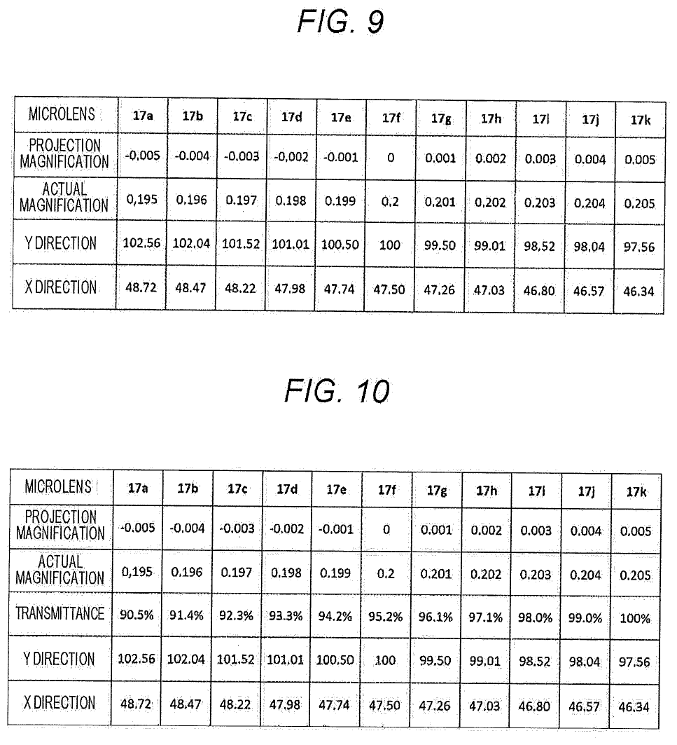

FIG. 9 is a table showing a correspondence relationship between the “projection magnification of microlens 17,” the “actual projection magnification,” and the “size of opening portion 16 of projection mask pattern 15” in the second example. Also, the opening portion 16 has a substantially rectangular shape, and the “size of the opening portion 16 of the projection mask pattern 15” is indicated by a length (Y direction) and a width (X direction). However, the opening portion 16 does not necessarily need to have a substantially rectangular shape and, in this example, the “size of the opening portion 16 of the projection mask pattern 15” may be indicated by an area or the like.

As described in the first example, since each of the plurality of microlenses 17 included in the microlens array 13 has a certain variation, and a variation in the lens curvature occurs due to the variation, the projection magnification (the projection magnification of the laser light 14 on the substrate 30) may be different for each of the plurality of microlenses 17. Therefore, when the sizes of the opening portions 16 of the projection mask pattern 15 are substantially the same, a range in which the laser annealing process is performed on the substrate 30 differs for each of the microlenses 17 because the projection magnifications are different. As a result, variation in the electron mobility of the polysilicon thin film formed on the substrate 30 occurs, and thus there is a problem that variation in the characteristics of the thin film transistor 20 occurs.

Therefore, in the second example, the projection magnification of each of the plurality of microlenses 17 included in the microlens array 13 is measured, and the size of the opening portion 16 of the projection mask pattern 15 is adjusted on the basis of the measured projection magnification. As a result, ranges of the laser annealing performed by the laser light 14 transmitted through each of the plurality of microlenses 17 become substantially the same, and thus the variation in the characteristics of the thin film transistor 20 can be reduced.

As exemplified in FIG. 9, for a microlens 17f of which the projection magnification is “0” (the actual projection magnification is “0.2”) among the microlenses 17 included in the microlens array 13, the “size of the opening portion 16 of the projection mask pattern 15” is set so that the length (the Y direction) is “100 (μm)” and the width (the X direction) is “47.5 (μm).” That is, on the basis of when the projection magnification is a predetermined value, the “size of the opening portion 16 of the projection mask pattern 15” in that example is set so that the length (the Y direction) is “100 (μm)” and the width (the X direction) is “47.5 (μm).” As a result, since the actual projection magnification is “0.2,” the laser annealing is performed in a range of “20 (μm)” in the length (the Y direction) and “9.5 (μm)” in the width (the X direction) on the substrate 30.

Then, the transmittance of the laser light through each of the other microlenses 17 is set on the basis of the projection magnification of the microlens 17k having a transmittance of 100%. For example, for the microlens 17a of which the projection magnification is “−0.005” (the actual projection magnification is “0.195”), the “size of the opening portion 16 of the projection mask pattern 15” may be set to have a length (the Y direction) of “102.56 (μm),” and a width (the X direction) of “48.72 (μm).” Further, since the projection magnification of the microlens 17b is “−0.004” (the actual projection magnification is “0.196”), the “size of the opening portion 16 of the projection mask pattern 15” is set to have a length (Y direction) of “102.04 (μm)” and a width (the X direction) of “47.98 (μm).” The “size of the opening portion 16 of the projection mask pattern 15” is similarly set for each of the other microlenses 17c to 17j.

As exemplified in FIG. 5, since the projection magnifications of the plurality of microlenses 17 included in the microlens array 13 are different from each other, the size of the opening portion 16 corresponding to each of the microlenses 17 is adjusted according to the correspondence relationship exemplified in FIG. 9 on the basis of the projection magnification of each of the microlenses 17. For example, since the projection magnification of the microlens 17a in FIG. 5 is “+0.001” (the actual projection magnification is “0.201”), the size of the opening portion 16 corresponding to the microlens 17a is set to have a length (Y direction) of “99.50 (μm)” and a width (the X direction) of “47.26 (μm).” Further, since the projection magnification of the microlens 17b in FIG. 5 is “−0.005,” the size of the opening portion 16 corresponding to the microlens 17b is set to have a length (Y direction) of “102.56 (μm)” and a width (the X direction) of “48.72 (μm).” Similarly, the size of the opening portion 16 corresponding to each of the plurality of microlenses 17 included in the microlens array 13 is adjusted. As a result, since each of the opening portions 16 of the projection mask pattern 15 has a size on the basis of the projection magnification of the corresponding microlens 17, the range of the laser annealing performed by the laser light 14 transmitted through the microlens 17 is substantially the same.

As described above, since the size of the opening portion 16 of the projection mask pattern 15 is set on the basis of the projection magnification of the microlens 17, the range of the laser annealing performed by the laser light 14 transmitted through each of the plurality of microlenses 17 becomes substantially the same, and thus it is possible to reduce the variation in the characteristics of the thin film transistor 20.

### THIRD EXAMPLE

A third example includes the transmittance of each of the plurality of microlenses 17 (the first example) and the size of the opening portion 16 of the projection mask pattern 15 (the second example) being set on the basis of the projection magnification of the microlens 17.

FIG. 10 is a table showing a correspondence relationship between the “projection magnification of the microlens 17,” the “actual projection magnification,” the “transmittance to be set in the opening portion of the projection mask pattern 15,” and the “size of the opening portion 16 of projection mask pattern 15” according to the third example. In FIG. 10, since the correspondence relationship between the “projection magnification of the microlens 17,” the “actual projection magnification,” and the “transmittance to be set in the opening portion of the projection mask pattern 15” is the same as that exemplified in FIG. 6, detailed description thereof will be omitted. Furthermore, in FIG. 10, since the correspondence relationship between the “projection magnification of the microlens 17,” the “actual projection magnification,” the “size of the opening portion 16 of projection mask pattern 15” is the same as that exemplified in FIG. 9, detailed description thereof will be omitted.

In the third example, the transmittance to be set in the opening portion of the projection mask pattern 15 is set and the size of the opening portion 16 in the projection mask pattern 15 is also set on the basis of the correspondence relationship exemplified in FIG. 10 and the projection magnification of the microlens 17. As a result, (1) the transmittance of each of the plurality of microlenses 17 (that is, the transmittance of the opening portion (the transmission region) of the projection mask pattern 15) is set so that the energy density of the laser light 14 on the substrate is substantially the same, and (2) the size of the opening portion 16 of the projection mask pattern 15 is also adjusted on the basis of the projection magnification. As a result, since the laser light 14 transmitted through the projection mask pattern 15 has substantially the same energy density on the substrate 30, and the range of the laser annealing performed by the laser light 14 transmitted through each of the plurality of microlenses 17 is substantially the same, it is possible to reduce the variation in the characteristics of the thin film transistor 20.

As exemplified in FIG. 5, since the projection magnifications of the plurality of microlenses 17 included in the microlens array 13 are different from each other, the size of the opening portion 16 corresponding to each of the microlenses 17 is adjusted according to the correspondence relationship exemplified in FIG. 10 on the basis of the projection magnification of each of the microlenses 17. For example, since the projection magnification of the microlens 17a in FIG. 5 is “+0.001” (the actual projection magnification is “0.201”), the transmittance of the laser light 14 through the opening portion 16a is set to “96.1%,” and the size of the opening portion 16 corresponding to the microlens 17a is set to have a length (the Y direction) of “99.50 (μm)” and a width (the X direction) of “47.26 (μm).”

Further, since the projection magnification of the microlens 17b in FIG. 5 is “−0.005,” the transmittance of the laser light 14 through the opening portion 16b is set to “90.5%,” and the size of the opening portion 16 corresponding to the microlens 17b is set to have a length (the Y direction) of “102.56 (μm)” and a width (the X direction) of “48.72 (μm).” Similarly, transmittance of the opening portion 16 corresponding to each of the plurality of microlenses 17 included in the microlens array 13 and the size of the opening portion 16 are adjusted. As a result, since each of the opening portions 16 of the projection mask pattern 15 has a transmittance at which the energy density on the substrate 30 is substantially the same and has a size on the basis of the projection magnification of the corresponding microlens 17, the energy density of the laser light 14 transmitted through each of the microlenses 17 becomes substantially the same, and the range of the laser annealing becomes substantially the same.

As described above, in the third example, (1) transmittance of each of the plurality of microlenses 17 (that is, the transmittance of the opening portion (the transmission region) of the projection mask pattern 15) is set so that the energy density of the laser light 14 on the substrate is substantially the same, and (2) the size of the opening portion 16 of the projection mask pattern 15 is adjusted on the basis of the projection magnification. As a result, since the laser light 14 transmitted through the projection mask pattern 15 has substantially the same energy density on the substrate 30, and the range of the laser annealing performed by the laser light 14 transmitted through each of the plurality of microlenses 17 is substantially the same, it is possible to reduce the variation in the characteristics of the thin film transistor 20.

### FOURTH EXAMPLE

A fourth example includes the laser annealing being performed using one projection lens 18 instead of the microlens array 13.

In a single projection lens, for example, the projection magnification of a peripheral portion may be different from that of a center portion due to an influence of distortion or the like. When the projection magnification is different, the variation in the energy density of the laser light irradiated on the substrate 30 occurs, and thus the variation in the result of the annealing process is caused. Further, when the sizes of the opening portions 16 of the projection mask pattern 15 are substantially the same, a range of the substrate 30 to be laser-annealed differs according to the peripheral portion and the center portion of the projection lens 18 because the projection magnification is different. As a result, since the variation in the electron mobility of the polysilicon thin film formed on the substrate 30 also occurs, and thus there is a problem that the variation in the characteristics of the thin film transistor 20 occurs.

Therefore, in the fourth example, uniform irradiation is realized by changing transmittance of the opening portion 16 of the projection mask pattern 15 provided on the single projection lens 18. For example, in the single projection lens, when the peripheral portion has a lower projection magnification than that in the central portion, it is possible to realize the uniform irradiation over the entire projection mask pattern 15 by increasing the transmittance of the “opening portion 16 at the center portion of the projection mask pattern 15” corresponding to the center portion of the projection lens and setting the transmittance of the “opening portion 16 at the peripheral portion of the projection mask pattern 15” corresponding to the peripheral portion of the projection lens to be lower than that at the center portion.

In addition, the projection magnification is measured at each of predetermined portions of the single projection lens 18, and the size of the opening portion 16 of the projection mask pattern 15 is adjusted on the basis of the measured projection magnification. As a result, since the range of the laser annealing performed by the laser light 14 transmitted through each of the predetermined portions of the single projection lens 18 is substantially the same, it is possible to reduce the variation in the characteristics of the thin film transistor 20.

Also, in the fourth example, only one or both of (1) changing of the transmittance of the opening portion 16 of the projection mask pattern 15 and (2) adjusting of the size of the opening portion 16 of the projection mask pattern 15 may be performed.

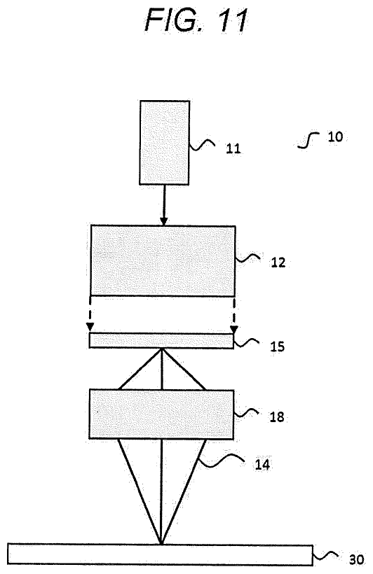

FIG. 11 is a view showing a configuration of the laser irradiation device 10 according to the fourth example. As shown in FIG. 11, the laser irradiation device 10 according to the fourth example includes a laser light source 11, a coupling optical system 12, a projection mask pattern 15, and a projection lens 18. Since the laser light source 11 and the coupling optical system 12 have the same configuration as the laser light source 11 and the coupling optical system 12 according to the first example shown in FIG. 1, detailed description thereof will be omitted. Further, since the projection mask pattern has the same configuration as the projection mask pattern in the first example, detailed description thereof will be omitted.

The laser light is transmitted through an opening (a transmission region) of the projection mask pattern 15 (not shown) and is radiated on a predetermined region of the amorphous silicon thin film 21 by the projection lens 18. As a result, the predetermined region of the amorphous silicon thin film 21 is instantaneously heated and melted, and a part of the amorphous silicon thin film 21 becomes a polysilicon thin film 22.

Also in the fourth example, the laser irradiation device 10 radiates the laser light 14 at a predetermined cycle, moves the substrate 30 during a time when the laser light 14 is not radiated, and irradiates a portion of the next amorphous silicon thin film 21 with the laser light 14. Also in the fourth example, as shown in FIG. 3, the amorphous silicon thin film 21 is disposed on the substrate 30 at a predetermined interval “H” in the movement direction. Then, the laser irradiation device 10 radiates the laser light 14 to a portion of the amorphous silicon thin film 21 disposed on the substrate 30 at a predetermined cycle.

When the projection lens 18 is used, the laser light 14 is converted by a magnification of an optical system of the projection lens 18. That is, a pattern of the projection mask pattern 15 (a pattern of the opening portion 16) is converted by the magnification of the optical system of the projection lens 18, and a predetermined region on the substrate 30 is laser-annealed.

That is, the mask pattern of the projection mask pattern 15 (the pattern of the opening portion 16) is converted by the magnification of the optical system of the projection lens 18, and a predetermined region on the substrate 30 is laser-annealed. For example, when the magnification of the optical system of the projection lens 18 is about two times, the mask pattern of the projection mask pattern 15 is multiplied by about ½ (0.5), and the predetermined region of the substrate 30 is laser-annealed. The magnification of the optical system of the projection lens 18 is not limited to about two times and may be any magnification. In the mask pattern of the projection mask pattern 15, the predetermined region on the substrate 30 is laser-annealed according to the magnification of the optical system of the projection lens 18. For example, when the magnification of the optical system of the projection lens 18 is four times, the mask pattern of the projection mask pattern 15 (the pattern of the opening portion 16) is multiplied by about ¼ (0.25), and the predetermined region of the substrate 30 is laser-annealed.

Further, when the projection lens 18 forms an inverted image, a reduced image of the projection mask pattern 15 applied to the substrate 30 has a pattern rotated by 180 degrees around an optical axis of a lens of the projection lens 18. On the other hands, when the projection lens 18 forms an upright image, a reduced image of the projection mask pattern 15 applied to the substrate 30 remains as it is.

As described above, in the projection lens 18, for example, due to an influence of distortion and the like, the projection magnification of the peripheral portion may be different from that of the central portion. When the projection magnification is different, the variation in the energy density of the laser light irradiated on the substrate 30 occurs, and thus the variation in the result of the annealing process may be caused. Therefore, the variation in the electron mobility of the polysilicon thin film formed on the substrate 30 also occurs, and thus there is a problem that the variation in the characteristics of the thin film transistor 20 occurs.

Therefore, in the fourth example, the projection lens 18 may be divided into predetermined portions such as a central portion and a peripheral portion of the projection lens 18, the projection magnification is measured, and the transmittance of the laser light 14 of each of the other portions (a center portion or other peripheral portion) is adjusted on the basis of a portion (for example, a peripheral portion) having the lowest projection magnification among the measured projection magnifications. The energy density of the laser light 14 irradiated by each of the predetermined portions of the projection lens 18 on the substrate becomes substantially the same by adjusting the transmittance of the laser light 14. As a result, the electron mobility of the polysilicon thin film formed by the laser light 14 irradiated by the projection lens 18 is also substantially the same, and thus it is possible to reduce the variation in the characteristics of the thin film transistor 20.

As described above, in the fourth example, the transmittance of the opening portion 16 (the transmission region) of the projection mask pattern 15 corresponding to a predetermined portion of the projection lens 18 is adjusted to adjust the transmittance of the laser light 14 through the projection lens 18. Specifically, the projection magnification of each of the predetermined portions of the projection lens 18 is measured, and the transmittance of the opening portion 16 (the transmission region) of the projection mask pattern 15 corresponding to each of the other predetermined portions is set on the basis of the lowest projection magnification (the projection magnification of one of the predetermined portions) among the measured projection magnifications.

Since the transmittance in a predetermined portion of the projection lens 18 cannot be increased, the transmittance of each of the other portions is adjusted according to a portion at a position in which the projection magnification is the largest (that is, the lowest transmittance). For example, the transmittance of one portion having the largest projection magnification is set to 100%, and the transmittance of each of the other portions is set accordingly. In addition, the transmittance of one portion having the largest projection magnification does not necessarily need to be 100% and may be less than 100%.

When the sizes of the opening portions 16 of the projection mask pattern 15 are substantially the same, the range of the substrate 30 to be laser-annealed is different for each of the predetermined portions of the projection lens 18 because the projection magnification is different. As a result, the variation in the electron mobility of the polysilicon thin film formed on the substrate 30 occurs, and thus there is a problem that the variation in the characteristics of the thin film transistor 20 occurs.

Therefore, in the fourth example, the projection magnification of each of the predetermined portions of the single projection lens 18 is measured, and the size of the opening portion 16 of the projection mask pattern 15 is adjusted on the basis of the measured projection magnification. As a result, since the range of the laser annealing performed by the laser light 14 transmitted through each of the predetermined portions of the single projection lens 18 is substantially the same, it is possible to reduce the variation in the characteristics of the thin film transistor 20.

As described above, in the fourth example, (1) the transmittance of each of the predetermined portions of the single projection lens 18 (that is, the transmittance of the opening portion (the transmission region) of the projection mask pattern 15) is set so that the energy density of the laser light 14 on the substrate is substantially the same, and (2) the size of the opening portion 16 of the projection mask pattern 15 is adjusted on the basis of the projection magnification. As a result, since the laser light 14 transmitted through the projection mask pattern 15 has substantially the same energy density on the substrate 30, and the range of the laser annealing performed by the laser light 14 transmitted through each of the predetermined portions of the single projection lens 18 is substantially the same, it is possible to reduce the variation in the characteristics of the thin film transistor 20.

Further, as described above, in the fourth example, only one or both of (1) changing of the transmittance of the opening portion 16 of the projection mask pattern 15 and (2) adjusting of the size of the opening portion 16 of the projection mask pattern 15 may be performed.

In the above description, when there is a description such as “vertical,” “parallel,” “planar,” “orthogonal” or the like, the descriptions do not indicate strictly meaning of such terms. That is, “vertical,” “parallel,” “planar” and “orthogonal” allow tolerances and errors in design, manufacturing or the like and may mean “substantially vertical,” “substantially parallel,” “substantially planar” and “substantially orthogonal.” The tolerance or error means a unit within a range which does not deviate from the configuration, operation, and desired effect.

Further, in the above description, when there is a description such as “same,” “equal,” “different” or the like in a dimension and a size of an external shape, the descriptions do not indicate strictly meaning of such terms. That is, “same,” “equal” and “different” allow tolerances and errors in design, manufacturing, or the like and may mean “substantially same,” “substantially equal” and “substantially different.” The tolerance or error means a unit within a range which does not deviate from the configuration, operation, and desired effect.

Although this disclosure has been described with reference to the drawings and examples, it should be noted that those skilled in the art can easily make various changes and modifications based on the disclosure. Therefore, changes and modifications are included in the scope of the disclosure. For example, functions included in each means, each step, and the like can be rearranged not to be logically inconsistent, and a plurality of means, steps, and the like can be combined into one or divided. Further, configurations described in the above-described examples may be combined as appropriate.

1. A laser irradiation device comprising:
a light source that generates laser light;
a projection lens that radiates the laser light to a predetermined region of an amorphous silicon thin film deposited on a substrate; and
a projection mask pattern that is provided on the projection lens and has a plurality of opening portions so that a predetermined region of the amorphous silicon thin film is irradiated with the laser light,
wherein each of the plurality of opening portions has a transmittance based on a projection magnification of the projection lens.

2. The laser irradiation device according to claim 1, wherein:
the projection lens is a plurality of microlenses included in a microlens array capable of separating the laser light, and
each of the plurality of opening portions has a transmittance based on a projection magnification of the microlenses.

3. The laser irradiation device according to claim 2, wherein each of the plurality of opening portions has a transmittance determined on the basis of a difference between a maximum value of the projection magnification of each of the plurality of microlenses and the projection magnification of the microlenses.

4. The laser irradiation device according to claim 2, wherein:
the transmittance of one microlens, at which the projection magnification is a maximum value, among the plurality of microlenses is a predetermined transmittance, and
each of other microlenses among the plurality of microlenses has a transmittance determined on the basis of the predetermined transmittance and a difference between the maximum value and the projection magnification of each of the other microlenses.

5. The laser irradiation device according to claim 3, wherein:
the transmittance of one microlens, at which the projection magnification is a maximum value, among the plurality of microlenses is a predetermined transmittance, and
each of other microlenses among the plurality of microlenses has a transmittance determined on the basis of the predetermined transmittance and a difference between the maximum value and the projection magnification of each of the other microlenses.

6. The laser irradiation device according to claim 2, wherein each of the plurality of opening portions has a size determined on the basis of the projection magnification of each of the plurality of microlenses.

7. The laser irradiation device according to claim 3, wherein each of the plurality of opening portions has a size determined on the basis of the projection magnification of each of the plurality of microlenses.

8. The laser irradiation device according to claim 4, wherein each of the plurality of opening portions has a size determined on the basis of the projection magnification of each of the plurality of microlenses.

9. The laser irradiation device according to claim 5, wherein each of the plurality of opening portions has a size determined on the basis of the projection magnification of each of the plurality of microlenses.

10. The laser irradiation device according to claim 6, wherein each of the plurality of opening portions has a rectangular shape, and a length and a width of the rectangular shape are determined on the basis of the projection magnification of each of the plurality of microlenses.

11. The laser irradiation device according to claim 1, wherein the projection lens radiates the laser light to an amorphous silicon thin film deposited to a region corresponding to a region between a source electrode and a drain electrode included in a thin film transistor and forms a polysilicon thin film.

12. A laser irradiation method comprising:
generating laser light;
irradiating a predetermined region of an amorphous silicon thin film deposited on a substrate with the laser light using a projection lens having a projection mask pattern including a plurality of opening portions; and
moving the substrate in a predetermined direction whenever the laser light is radiated,
wherein each of the plurality of opening portions has a transmittance based on a projection magnification of the projection lens.

13. The laser irradiation method according to claim 12, wherein:
the projection lens is a plurality of microlenses included in a microlens array capable of separating the laser light, and
each of the plurality of opening portions has a transmittance based on a projection magnification of the microlenses.

14. The laser irradiation method according to claim 13, wherein each of the plurality of opening portions has a transmittance determined on the basis of a difference between a maximum value in the projection magnification of each of the plurality of microlenses and the projection magnification of the microlens.

15. The laser irradiation method according to claim 13, wherein each of the plurality of opening portions has a size determined on the basis of the projection magnification of each of the plurality of microlenses.

16. A projection mask disposed on a projection lens that radiates laser light generated from a light source,
wherein a plurality of opening portions are provided in the projection mask so that a predetermined region of an amorphous silicon thin film deposited on a substrate that moves in a predetermined direction is irradiated with the laser light, and
each of the plurality of opening portions has a transmittance based on a projection magnification of the projection lens.

17. The projection mask according to claim 16, wherein:
the projection lens is a plurality of microlenses included in a microlens array capable of separating the laser light, and
each of the plurality of opening portions has a transmittance based on a projection magnification of the microlenses.

18. The projection mask according to claim 17, wherein each of the plurality of opening portions has a transmittance determined on the basis of a difference between a maximum value of the projection magnification of each of the plurality of microlenses and the projection magnification of the microlenses.

19. The projection mask according to claim 17, wherein each of the plurality of opening portions has a size determined on the basis of the projection magnification of each of the plurality of microlenses.
